(19) United States
(12) Patent Application Publication
(10) Pub. No.: US 2026/0086167 A1
(43) Pub. Date: Mar. 26, 2026

(54) SYSTEM AND METHOD FOR DETECTING VOLTAGE SUPPRESSION IN A BATTERY POWER SOURCE

(71) Applicant: Solid Power Operating, Inc., Louisville, CO (US)

(72) Inventor: Forrest A.L. Laskowski, Bend, OR (US)

(21) Appl. No.: 19/339,128

(22) Filed: Sep. 24, 2025

Related U.S. Application Data
(60) Provisional application No. 63/698,325, filed on Sep. 24, 2024.

(51) Int. Cl. G01R 31/392; G01R 31/367; G01R 31/388; H01M 10/42; H01M 10/44

(52) U.S. Cl. CPC G01R 31/392; G01R 31/367; G01R 31/388; H01M 10/4285; H01M 10/443

(57) ABSTRACT

A method for determining a condition indicating imminent thermal runaway in a power source includes changing a state of charge of the power source during one of a plurality of charge cycles and a plurality of discharge cycle. In response to the state of charge in each of the one of the plurality of charge cycles and the plurality of discharge cycles, the method includes matching a first condition measuring the state of charge of the power source and determining an overpotential value based on the measured state of charge. The method also includes determining a trend based on a plurality of the overpotential values and identifying an indication of possible thermal runaway in the power source based on the trend indicating a downward trend of the plurality of overpotential values.

### TECHNICAL FIELD

Aspects of the disclosure relate to battery-type voltage sources, and more particularly to detecting suppression in the voltage of the voltage source.

### BACKGROUND

With the ever-increasing adoption of mobile devices, electric automobiles, and the development of Internet-of-Things devices, the need for battery technologies with improved reliability, capacity (Ah), thermal characteristics, lifetime and recharge performance has never been greater. While some battery technologies offer potential increases in safety, packaging efficiency, and enable new high-energy chemistries, further improvements are needed.

In one example, battery thermal runaway is a phenomenon that can occur when internal heating causes heat-generating reactions within the battery, leading to self-sustaining reactivity that can cause the battery to catch fire or explode. The initial heating event may be caused by unforeseeable reactions within the cell, by common abuse conditions (e.g. short circuit testing), or by external heat. Once a sufficient internal temperature is reached, a domino-like effect occurs where unwanted side reactions continually produce more heat, thereby triggering additional nearby reactions. In battery packs, the rise in temperature can also affect nearby batteries, causing the entire battery system to catch fire.

It is with these observations in mind, among others, that aspects of the present disclosure were conceived.

### OVERVIEW

In accordance with one aspect of the present disclosure, method for determining a condition indicating imminent thermal runaway in a power source includes changing a state of charge of the power source during one of a plurality of charge cycles and a plurality of discharge cycle. In response to the state of charge in each of the one of the plurality of charge cycles and the plurality of discharge cycles, the method includes matching a first condition measuring the state of charge of the power source and determining an overpotential value based on the measured state of charge. The method also includes determining a trend based on a plurality of the determined overpotential values and identifying an indication of possible thermal runaway in the power source based on the trend indicating a downward trend of the plurality of overpotential values.

In accordance with another aspect of the present disclosure, an apparatus includes one or more computer readable storage media and program instructions stored on the one or more computer readable storage media. The program instructions executable by a processing system direct the processing system to change a state of charge of the power source during one of a plurality of charge cycles and a plurality of discharge cycles, measure the state of charge of the power source in each of the one of the plurality of charge cycles and the plurality of discharge cycles, and determine an overpotential value based on the measured state of charge. The program instructions also direct the processing system to compare the determined overpotential value with one or more previously determined overpotential values and identify an indication of possible thermal runaway in the power source based on the comparison.

In accordance with another aspect of the present disclosure, a system includes a DC power source, a power supply, and a controller. The controller is configured to cause the power supply to charge the DC power source during each of a plurality of charge cycles, determine an overpotential value for each of the plurality of charge cycles, compare the overpotential value with one or more historical overpotential values, and identify an indication of possible thermal runaway in the DC power source in response to an indication of a downward trend of the overpotential value in relation to the one or more historical overpotential values.

### BRIEF DESCRIPTION OF THE DRAWINGS

The drawings illustrate embodiments presently contemplated for carrying out the invention.

In the drawings:

FIG. 1 illustrates a schematic representation of a DC power system according to one or more aspects of this disclosure.

FIG. 2 is a block diagram of a battery-type power source according to one or more aspects of this disclosure.

FIG. 3 is a block diagram showing a battery cell arrangement according to one or more aspects of this disclosure.

FIG. 4 illustrates a plot showing potential overpotential measurements of a battery according to one or more aspects of this disclosure.

FIG. 5 illustrates a plot showing exemplary overpotential measurements of a healthy battery according to one or more aspects of this disclosure.

FIG. 6 illustrates a plot showing exemplary overpotential measurements of a battery indicating a condition trending toward thermal runaway according to one or more aspects of this disclosure.

FIG. 7 is a flowchart showing a method for detecting potential thermal runaway of a battery according to one or more aspects of this disclosure.

FIG. 8 is a block diagram showing voltage measurement options according to one or more aspects of this disclosure.

FIG. 9 illustrates a plot showing exemplary state of charge measurements of a charging battery according to one or more aspects of this disclosure.

FIG. 10 illustrates a plot showing exemplary state of charge measurements of a healthy charging battery according to one or more aspects of this disclosure.

FIG. 11 illustrates a plot showing exemplary state of charge measurements of an unhealthy charging battery indicating a condition trending toward thermal runaway according to one or more aspects of this disclosure.

FIG. 12 is a flowchart showing a method for detecting potential thermal runaway of a battery according to one or more aspects of this disclosure.

FIG. 13 is a block diagram illustrating an example computing system according to one or more aspects of this disclosure.

While the present disclosure is susceptible to various modifications and alternative forms, specific embodiments thereof have been shown by way of example in the drawings and are herein described in detail. It should be understood, however, that the description herein of specific embodiments is not intended to limit the present disclosure to the particular forms disclosed, but on the contrary, the intention is to cover all modifications, equivalents, and alternatives falling within the spirit and scope of the present disclosure. Note that corresponding reference numerals indicate corresponding parts throughout the several views of the drawings.

### DETAILED DESCRIPTION

Examples of the present disclosure will now be described more fully with reference to the accompanying drawings. The following description is merely exemplary in nature and is not intended to limit the present disclosure, application, or uses.

Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention, which is defined by the claims.

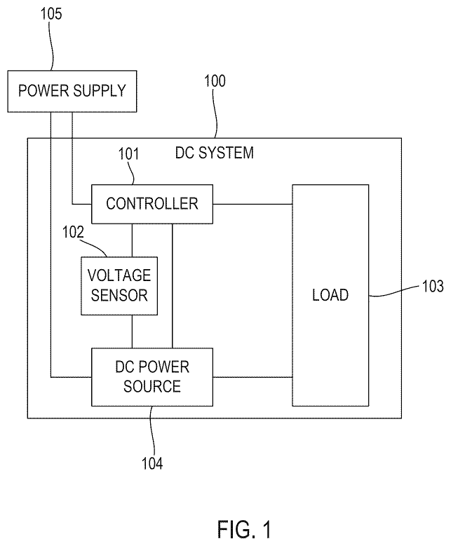

FIG. 1 illustrates a schematic representation of a direct current (DC) power system 100 configured to regulate and monitor electrical energy distribution within a DC environment. The system includes a controller 101 that serves as the central processing unit of the system, executing control algorithms and decision logic to maintain optimal performance. The controller 101 receives input signals from a voltage sensor 102 and other system components, enabling real-time adjustments to power flow and system parameters.

The controller 101 is also connected to a load 103 configured to receive power from a DC power source 104. In one embodiment, the DC power source 104 is rechargeable via a power supply unit 105 coupleable with the DC power system 100. The power supply unit 105 may be an external unit coupled with the DC power system 100 as needed for recharging of the DC power source 104, or the power supply unit 105 may be incorporated within the DC power system 100 on a permanent basis. The power supply unit 105 may be a voltage-to-voltage converter configured to convert an input electrical power (e.g., AC power from a power grid) into a DC power sufficient to provide charging energy to the DC power source 104. Alternatively, the power supply unit 105 may be a generator configured to convert an input mechanical power into the DC power sufficient to provide charging energy to the DC power source 104.

The DC power source 104 may include one or more energy generation or storage devices, such as batteries, photovoltaic cells, or fuel cells, configured to deliver direct current to the load 103, which represents any electrical or electronic device, subsystem, or network that consumes DC power, and may vary in demand depending on operational conditions.

The voltage sensor 102 monitors the voltage level across critical nodes within the system and, as described hereinbelow, within substructures of the DC power source 104. The voltage sensor 102 provides feedback to the controller 101 to ensure voltage stability, prevent overvoltage or undervoltage conditions, and support fault detection protocols.

Interconnections between these components are configured to support bidirectional communication and power flow, enabling dynamic response to changing load conditions, energy availability, and system health. The schematic layout depicted in FIG. 1 is exemplary and may be adapted to various configurations depending on application-specific requirements.

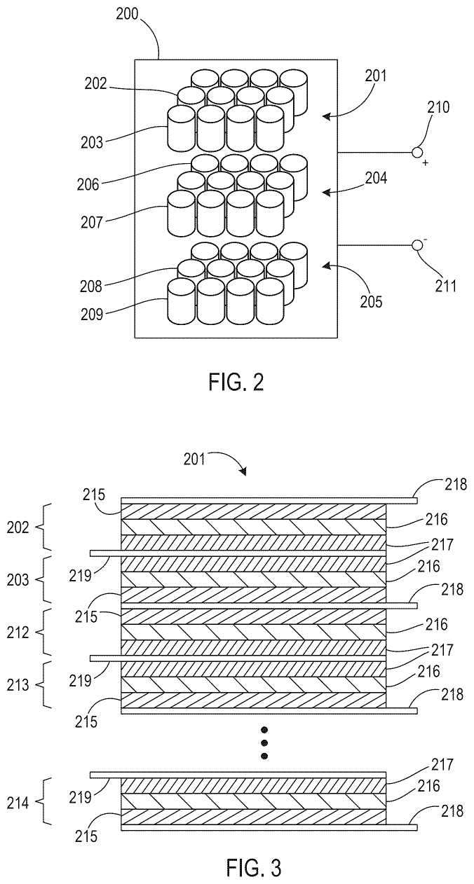

FIG. 2 illustrates a block diagram of a battery-type power source 200 according to one or more aspects of this disclosure. As shown, a plurality of cells are joined together in packs. A first pack 201 includes cells (such as cells 202, 203) joined together to produce a first voltage source capable of supplying voltages between a first fully-charged voltage level and a first fully-discharged voltage level. The cells 202, 203 are joined in an arrangement of parallel and/or series connections sufficient to source voltage between the designed charged/discharged voltage levels. Additional packs (such as packs 204, 205) contain respective cells 206/207 and 208/209 also configured to supply fully-charged through fully-discharged voltages. It may be desired that each cell and each pack yield substantially similar values when compared with one another. The packs 201, 204, 205, when combined, supply a battery voltage on output terminal 210, 211.

In one embodiment, the battery power source 200 is an all-solid-state battery, and each cell 202-203, 206-209 is an all-solid-state battery cell. FIG. 3 illustrates a block diagram showing a battery cell arrangement according to one or more aspects of this disclosure. In the illustrated diagram, first pack 201 is represented. However, it is contemplated that FIG. 3 may represent any of the packs within the battery power source 200.

As shown, the pack 201 includes a plurality of cells 202, 203, 212, 213, 214, each having a respective anode 215, separator 216, and cathode 217. An anode current collector 218 is electrically coupled to each anode 215, and a cathode current collector 219 is electrically coupled to each cathode 217. According to a first example, the anode current collector 218 is a positive electrode formed from a copper sheet coated with an anode electrolyte (e.g., a positive electrode active material) such as one having lithium sulfide or another lithium-based compound. The copper sheet may be coated on both sides with the anode electrolyte in preparation for stacking the layers as shown in FIG. 3. In this example, the cathode current collector 219 is a negative electrode formed from an aluminum sheet coated with a cathode electrolyte (e.g., a negative electrode active material), and the separator 216 is a solid electrolyte layer. Forming the pack 201 may include stacking a number of coated anode and cathode sheets with the separator 216 separating each layer.

Each cell 202, 203, 212, 213, 214 produces a voltage at the cell level, and together, they produce a pack voltage. Referring as well to FIG. 2, the number of cells illustrated in FIG. 3 matches the number of cells illustrated in each pack 201, 204, 205. While twelve cells are illustrated in FIG. 2 for purposes of discussion herein, it is contemplated that the number of individual cells in each pack 201, 204, 205 may be more or less than that shown and discussed.

In a battery power source such as the source 200 discussed herein, an overpotential occurs that is understood as the potential difference (or voltage measurement difference) between a thermodynamically determined voltage for a given state of charge (determined when the cell is at rest) and the voltage observed during charge or discharge at the same given state of charge. For a rechargeable battery such as the battery power source 200, the battery acts as a galvanic cell that converts chemical energy into electrical energy when discharging. That is, the battery acts as a galvanic cell when it is providing output voltage. When being charged, the battery acts as an electrolytic cell as it converts electrical energy provided to the cell to chemical energy. The conversions between electrical and chemical energy is known as a redox reaction. A redox reaction is a process where oxidation and reduction occur simultaneously. Oxidation is a process in which a substance loses electrons. Reduction is a process in which a substance gains electrons.

Electrolysis in an electrolytic cell occurs when DC current is applied through the electrolyte, resulting in a chemical reaction between electrodes and the separation of elements (molecules, atoms and ions). During this process, a transfer of electrons also occurs at the anode and cathode. A decomposition potential is the voltage needed for electrolysis to occur. The potential difference between decomposition potential (actual voltage) and the reduction potential (thermodynamically determined) is the overpotential required for decomposition.

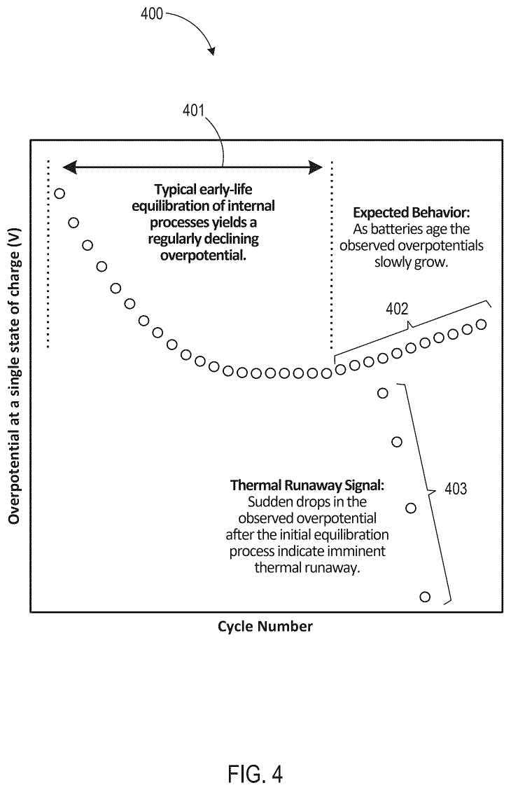

FIG. 4 illustrates a plot 400 showing exemplary values of overpotential that may be exhibited in a battery under various conditions. In an early life of the battery as shown in an initial period 401, a typical early-life equilibtation of internal processes yields a regularly declining overpotential. As shown, in successive charge or discharge cycles (each cycle represented by a circular value shown within the plot), the values of overpotential are expected to decline, reaching a floor or minimum value. As the internal processes equilibrate, the decline of overpotential values ceases, and in the case of a healthy battery, the internal processes in each of the charge/discharge cycles tend to cause the overpotential values to slowly grow over time as shown by measurement values 402. Thus, a trend of slowly growing overpotential values is expected in a healthy battery.

However, an unhealthy battery may deviate from the slowly growing overpotential values (e.g., measurement value 402) by exhibiting sudden drops in observed overpotential when the upward trend would be expected. For example, measurement values 403 illustrate a decline in the overpotential values after the initial period 401 in an alternate trajectory instead of an upward trend as shown in the measurement value 402. A decline or dropping of the overpotential values at this stage of battery life indicates a change in the internal processes of the battery that could result in a thermal runaway of the battery. Detection of any indicator showing a potential of a battery to enter thermal runaway can be used in mediation efforts to stop or slow any potential thermal runaway.

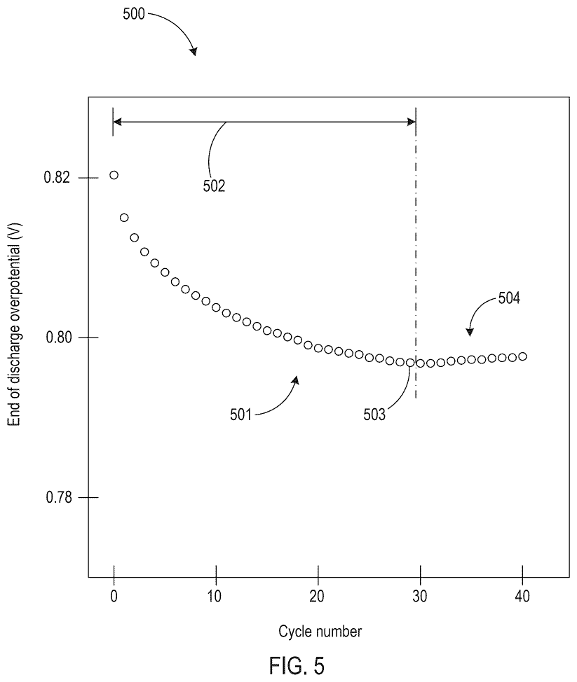

FIG. 5 illustrates a plot 500 showing exemplary measurements of overpotential of a healthy battery according to one or more aspects of this disclosure. The measurement values 501 illustrated in FIG. 5 were performed at the end of successive discharge cycles of a subject battery and represent measurements for the subject battery experienced under unique and/or specific conditions including temperature and rate of discharge. Measurement values for other batteries will be unique to them, and the example illustrated in FIG. 5 shows the kind of response that may be observed in other batteries of similar makeup. Thus, the number and trend of overpotential values illustrated in FIG. 5 and throughout this disclosure are exemplary only. The overpotential values may be measured, however, at other points within the charge/discharge cycle of the battery. For example, the measurement values may occur at the end of the charge cycle or at a same point within either the charge cycle or the discharge cycle. During an initial period 502 (e.g., through cycle number 29 at overpotential value 503), the values of the overpotential of a newly manufactured battery will reduce as relevant processes within the cell equilibrate. After the settling period 502, the overpotential values will stop falling. Ideally, the overpotential values will level off at a given value and will stay relatively flat across the charge/discharge cycles of the battery over its lifetime. However, in real-world applications, the overpotential values will tend to increase over time. The overpotential values 504 illustrated in FIG. 5 after the initial period 502 illustrate an increasing trend. In part, the increase in overpotential values as the battery experiences use can be caused by inefficient transfer of electrons to ions (or vice versa) due to the nature of the materials within the battery and by resistance losses caused by changing resistance within the battery cell components such as increases in charge-transfer resistances at the electrodes and ionic resistance through the electrolyte. Other factors such as mass transport losses and increasing current density can also cause overpotential to rise.

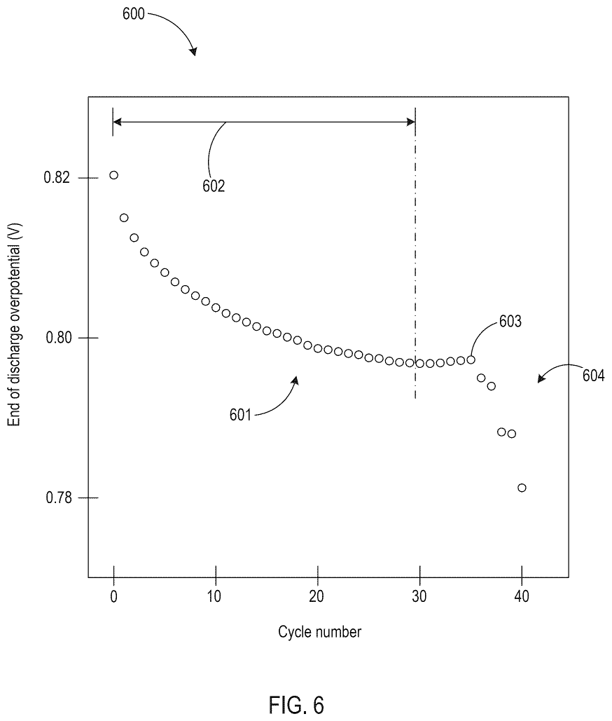

FIG. 6 illustrates a plot 600 showing exemplary measurements of overpotential of an unhealthy battery according to one or more aspects of this disclosure. The overpotential values 601 measured during the initial period 602 are similar to the initial period 502 of the plot 500 of FIG. 5. However, after the overpotential value 603 measured at cycle number 35, the subsequent overpotential values 604 begin to fall significantly. A sudden fall in the end-of-discharge overpotential may indicate the introduction of a soft short that may be developing into a hard short. The reduction of overpotential values measured at cycle numbers 36-40 indicate a battery experiencing an increase in voltage efficiency. While having a high voltage efficiency battery can considered a target outcome of battery research, the increase in efficiency caused by a decrease in overpotential compared with a settled-in overpotential value trajectory can indicate one or more imminent undesirable battery conditions. In one example, through usage of the battery over multiple charge and discharge cycles, the formation of a low-resistance path in the anode material or cathode material (e.g., anode 215 or cathode 217 of FIG. 3) and through the separator between them toward the opposite material can create a short-circuit connection between the anode and cathode. The short-circuit connection may be, for example, a small filament undesirably formed between the anode and cathode. As the short circuit forms, and as more short-circuit connections form, the battery spontaneously discharges, which contributes to an apparent reduction in the overpotential values 604.

A thin filament causing a short-circuit connection may be subject to large amounts of relative current flowing between the shorted anode and cathode. The high current flowing through the formed thin filament causes the filament to heat up significantly, altering the thermal nature of the battery. As the temperature of the battery in one area increases, additional internal changes can be generated as a result. The internal temperatures of one or more areas of the battery may start to rise uncontrollably and become self-sustaining. Additionally, as the temperature rises, the current also increases, which can cause a domino effect of increasing temperature and current. A chain reaction as the temperatures and current rise that spreads within the battery and possible to neighboring batteries results in a thermal runaway that can cause effects such as the battery system exploding and/or catching fire.

A consistent suppression in the overpotential at any state of charge is unexpected behavior since it would suggest improvement in battery performance, with cycling. In practice, battery ageing tends to invariably lead to diminished performance, cycle-over-cycle.

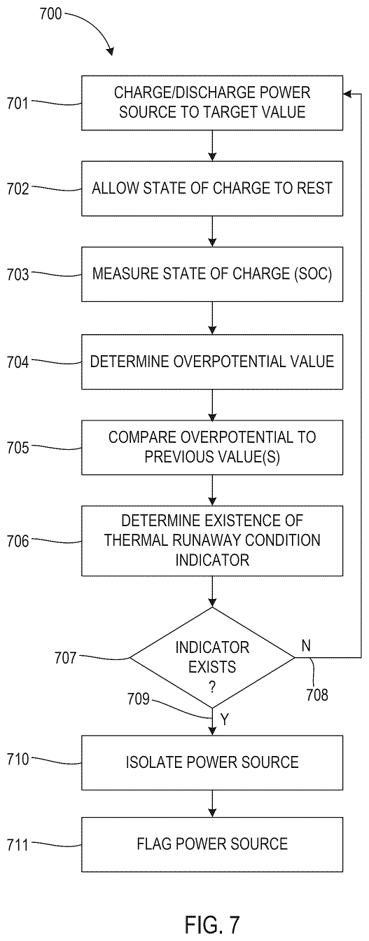

By measuring the overpotential values (e.g., 504, 604), conditions related to imminent thermal runaway events can be anticipated and prevented. FIG. 7 illustrates a flowchart showing a method 700 for detecting potential thermal runaway of a battery according to one or more aspects of this disclosure. A target power source is charged or discharged to a predetermined target value at step 701. As previously described, the measured overpotential values illustrated in FIGS. 5 and 6 were obtained after a discharge of the target battery. However, charging the target battery to its designed full state of charge level or to an alternate state of charge level is also contemplated herein. After the target value of the state of charge is reached, the charge or discharge cycle is halted or ceased, and the state of charge is allowed to rest at step 702. The resting period allows the potential to settle to the thermodynamic limit, which allows for the calculation of the overpotential at the state of charge. At step 703, the voltage or state of charge of the target power source is measured.

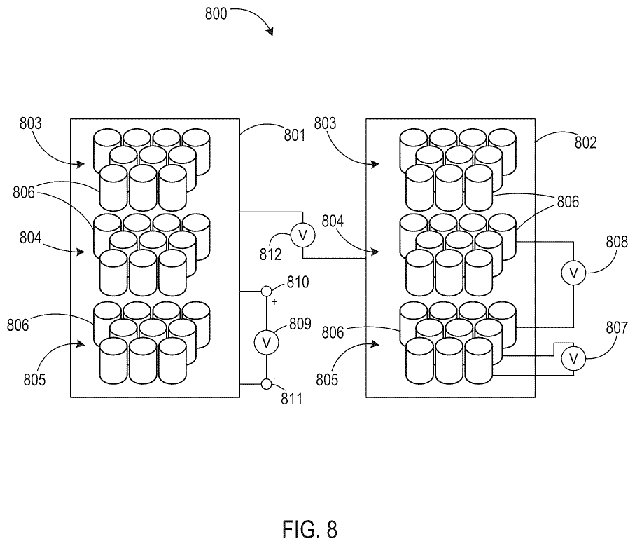

Referring to FIG. 8, a block diagram is shown of a variety of voltage measurement options according to one or more aspects of this disclosure. A battery system 800 is shown including a pair of batteries 801, 802 that may be similar to battery power source 200 of FIG. 2. For example, each battery 801, 802 includes a plurality of packs 803, 804, 805 of cells 806. As contemplated herein, the method 700 and determination of thermal runaway factors may be performed on a cell level, a pack level, a battery level, and/or on a system level. To perform overpotential voltage measurements on the cell level in one example, a voltage measurement device 807 is connected to one or more of the individual cells 806 of a pack. Multiple voltage measurement devices 807 may be used for a single pack, and multiple packs may include cell level voltage measurements. In another example, a voltage measurement device 808 is connected between multiple packs such as between packs 804, 805 as illustrated. It is contemplated that multiple voltage measurement devices 808 may be used among the various packs within a battery (e.g., battery 801 or battery 802). In another example, a voltage measurement device 809 is coupled to output terminals 810, 811 of a battery (e.g., battery 801 or battery 802) for performing overpotential voltage measurements on the battery level. In yet another example, a voltage measurement device 812 is connected to the batteries 801, 802 for performing overpotential voltage measurements on the system level.

Returning to FIG. 7, the state of charge measured at step 703 is compared with the predetermined target value to determine an overpotential value at step 704. For example, the overpotential value may be determined based on a difference between the state of charge measured after the resting period and the predetermined target value. At step 705, any of the overpotential values (e.g., the most recently determined overpotential value or any of the overpotential values stored in a historical log or database) may be compared with previous values. In a preferred embodiment, the most recently determined overpotential value is used. The overpotential value is compared with a number of prior measurements to determine (at step 706) a relationship of the most recent measurement with immediate prior measurements. To the measured data, the determined overpotential value from a given charge or discharge cycle (e.g., the most recent charge or discharge cycle) is compared to average values derived from the historical log or database of stored overpotential values. For example, the most recent determined overpotential value is compared to an average of a number of a subset of the next-most recently stored overpotential values (e.g., to an average of a subset of the three or five next-most recently stored values; however, other numbers of stored values used in the averaging calculation can be used). This comparison generates a value indicating whether the overpotential value under test is higher or lower than the average historical overpotential values.

Based on the comparison, a trend of the overpotential measurements can be determined. The trend may identify outliers such as single-point voltage measurements straying from neighboring measurements that have closely related values. The trend may also identify sudden changes due to a large change in the external temperature. For example, an overpotential value much higher or lower than both previous and subsequent values can indicate a measured value that can be ignored. However, based on a falling trend of subsequently measured values, a runaway event indicator is determined to exist. Thus, at step 707, the measured data is evaluated to determine whether the thermal runaway indicator event exists. If not (708), such as when the current and previous overpotential values (extracting any outlier values) indicate a steady upward trend, no thermal runaway indicator is determined to exist, and the method 700 returns to step 701 to continue as described in a subsequent charge or discharge cycle.

If a thermal runaway indicator is indicated (709) by an analysis of the overpotential value data, additional steps can be performed to reduce the chance of the battery actually experiencing a thermal runaway. For example, at step 710, the power source that may be subject to an impending thermal runaway event may be isolated from the pack, battery, or system by removing the power source from any connection to other components and from any additional charge or discharge cycle. By isolating and stopping use of the unhealthy power supply, the internal temperature can be allowed to fall to reduce the chances that an actual thermal runaway event will occur. Further, at step 711, the threatened power source may be flagged in software for display to a user to allow replacement of the unhealthy power source with a healthy one.

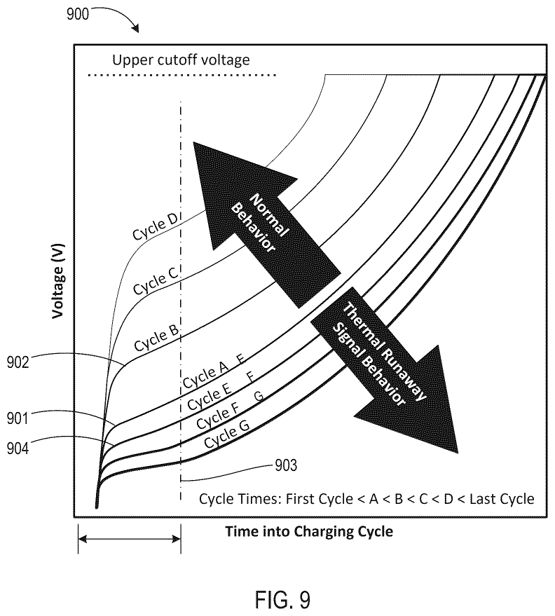

FIG. 9 illustrates a plot 900 showing behavior of a battery during charging according to one or more aspects of this disclosure. A first cycle curve (Cycle A) 901 illustrates a baseline cycle for the plot 900. Similar to the increasing trend of overpotential values typically observable in the measurement value 402 of FIG. 4, the internal processes of a charging battery will cause the charging voltage to be increases or higher at similar times into a charging cycle compared with previous charging cycles. Thus, a subsequent cycle curve (Cycle B) 902 exhibits a higher voltage at a given time 903 than the base cycle curve 901 at the same time 903. Additional subsequent curves (e.g., Cycle C and Cycle D) exhibit further increased values at time 903. Thus, cycle times for the battery to reach the designated fully-charged state decrease over time over the life of the battery.

However, should the internal processes of the battery change such that the battery is led along a path toward experiencing a thermal runaway event, rather than experiencing higher voltages at the same time (e.g., time 903) along the charging cycle, a lower voltage can be experienced at the same time 903. For example, a cycle curve (Cycle E) 904 shows a lower voltage at time 903 than the cycle curve 901. Subsequent cycle curves (e.g., Cycle F and Cycle G) experience respective lower voltages yet, indicating that a thermal runaway event may be experienced by the battery absent mitigation efforts.

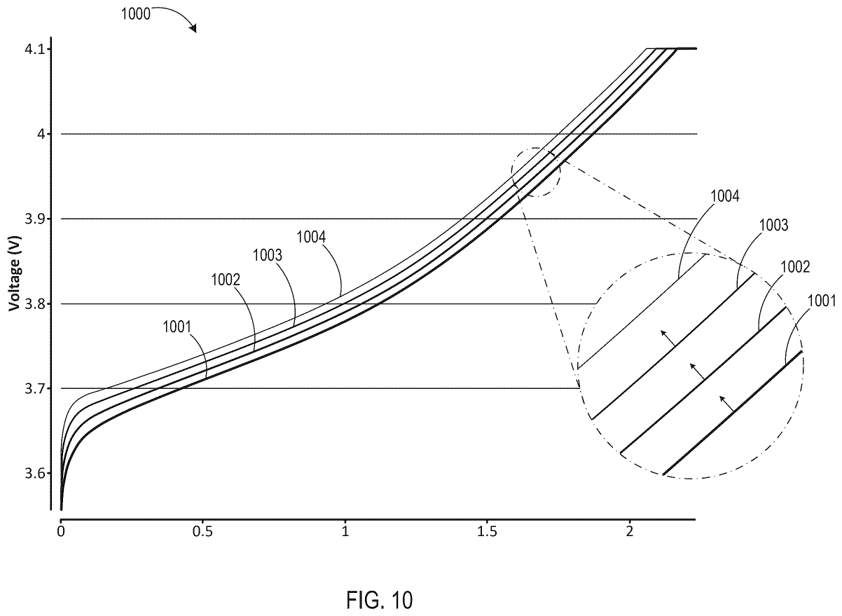

FIG. 10 illustrates a plot 1000 showing an exemplary voltage-time charging curve for a charging battery according to one or more aspects of this disclosure. As described above, after an initial period (e.g., initial period 502 shown in FIG. 5), the measured overpotential values slowly trend upward in a healthy battery. Plot 1000 illustrates voltage curves 1001, 1002, 1003, 1004 measured during multiple charge cycles where the target battery voltage source was charged from a same initial state of charge to the same final state of charge. Each curve 1001-1004 may represent multiple curves of distinct charge cycles that overlap one another and appear as one curve based on the resolution of the plot 1000. As with the upward trending overpotential values previously discussed, subsequent charging cycles of the target battery voltage source should experience a same or an upward trend of the voltage values at same time periods of the charging cycle. As an example, the one or more charging cycles represented by the voltage curve 1001 is lower at 1 hour than the one or more charging cycles represented by the voltage curve 1002. The one or more charging cycles of voltage curve 1002 were performed after the one or more charging cycles of the voltage curve 1001. The one or more charging cycles of voltage curve 1003 were performed after the one or more charging cycles of the voltage curve 1002, and the one or more charging cycles of voltage curve 1004 were performed after the one or more charging cycles of the voltage curve 1003. Thus, the curves 1001-1004 show an upward trend (as indicated by the arrows in the callout portion of FIG. 10) of the voltages as the number of charging cycles increases.

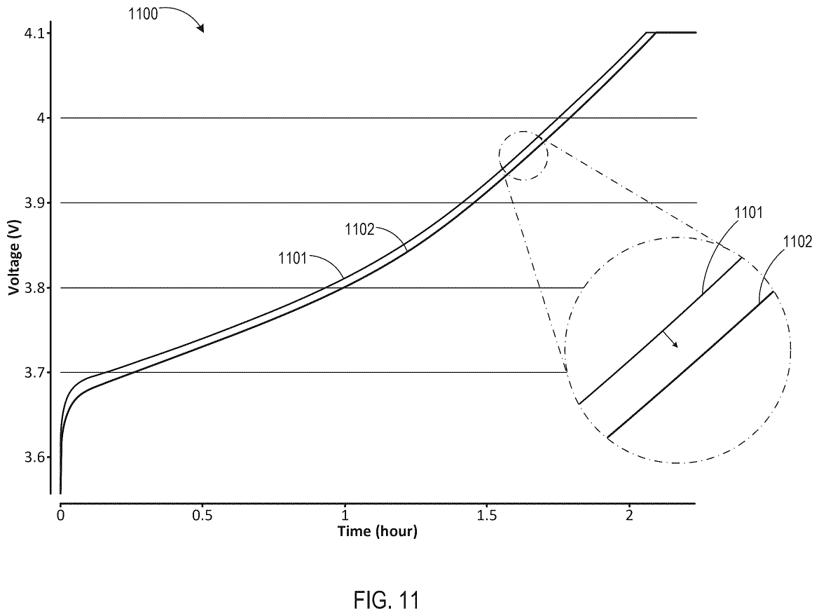

While the plot 1000 of FIG. 10 shows state of charge measurements of a healthy charging battery, FIG. 11 illustrates a plot 1100 showing exemplary state of charge measurements of an unhealthy charging battery indicating a condition trending toward thermal runaway according to one or more aspects of this disclosure. Shown are voltage curves 1101, 1102 showing voltage measurements during multiple charge cycles where the target battery voltage source was charged from a same initial state of charge to the same final state of charge. Each curve 1101, 1102 may represent multiple curves of distinct charge cycles that overlap one another and appear as one curve based on the resolution of the plot 1100. The values in voltage curve 1101 represent earlier charging cycles of the target battery voltage source than the charging cycles of the values in the voltage curve 1102. Instead of the upward trend of a healthy battery as shown in FIG. 10, the curves 1101, 1102 illustrate a downward trend in measured values as shown in the callout of FIG. 11. The depression in the voltage during charging may indicate a possible thermal runaway by the introduction of a soft short.

A consistent depression of voltage during constant-current charging will produce increased charging time to hit an upper voltage cutoff, suggesting improved battery performance. While there are reasons a pre-formed battery may exhibit the behavior, a post-formed battery does not generally show improvement with performance cycle-over-cycle.

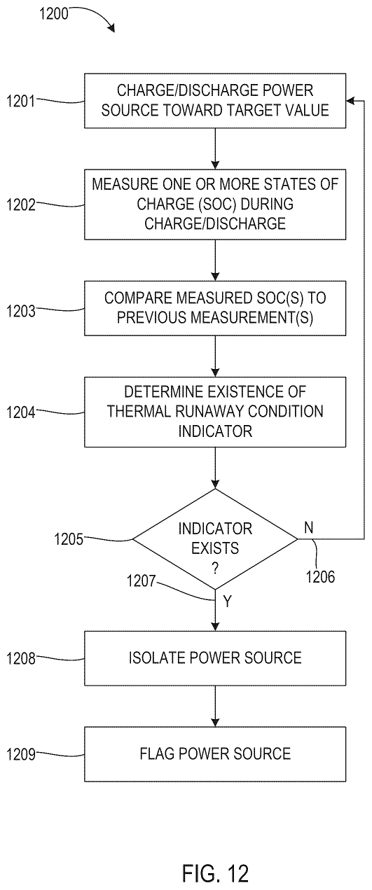

A possible and/or likely short-circuit connection (such as that described above) inside the charging target battery is indicated in the subsequent charging cycles that reduce the voltage levels at same time points compared to earlier charging cycles. The potential short-circuit connection can be detected via the method 1200 illustrated in FIG. 12 for detecting potential thermal runaway of a battery according to one or more aspects of this disclosure. A target power source is charged or discharged at a consistent current toward an upper or lower voltage cutoff at step 1201. At step 1202, the voltage is measured at one or more states of charge (e.g., measured at one or more specific time points) during the charging or discharging cycle. For example, any of the voltage measurement devices 807, 808, 809, 812 and their arrangements as discussed above may be used to measure the states of charge in step 1202. The state of charge measured at step 1202 is compared with a historical log or database of prior measurements at step 1203 for states of charge measured in previous cycles, to determine (at step 1204) a relationship of the most recent measurement with immediate prior measurements. Based on the comparison, a trend of the voltage measurements can be determined. A runaway event indicator is determined to exist based on a falling trend of subsequently measured values. Thus, at step 1205, the measured data is evaluated to determine whether the thermal runaway indicator event exists. If not (1206), such as when the current and previous overpotential values (extracting any outlier values) indicate a steady upward trend, no thermal runaway indicator is determined to exist, and the method 1200 returns to step 1201 to continue as described in a subsequent charge or discharge cycle.

If a thermal runaway indicator is indicated (1207) by an analysis of the overpotential value data, additional steps can be performed to reduce the chance of the battery beginning thermal runaway. For example, at step 1208, the power source that may be subject to an impending thermal runaway event may be isolated from the pack, battery, or system by removing the power source from any connection to other components and from any additional charge or discharge cycle. By isolating and stopping use of the unhealthy power supply, the internal temperature can be allowed to fall to reduce the chances that an actual thermal runaway event will occur. Further, at step 1209, the threatened power source may be flagged in software for display to a user to allow replacement of the unhealthy power source with a healthy one. Alternatively, the battery may be isolated from the main circuit and then slowly discharged through an auxiliary circuit. For some causes of thermal runaway (e.g. dendrites forming during fast charge rates) a slow discharge may effectively eliminate the shorting behavior, thereby improving the odds of preventing a thermal runaway event. Alternatively, the battery may be isolated from the main circuit and then supplied an AC signal through an auxiliary circuit. For some causes of thermal runaway (e.g., inhomogeneous deposition of Li) an AC signal may create a more conformal deposition, thereby improving the odds of preventing a thermal runaway event.

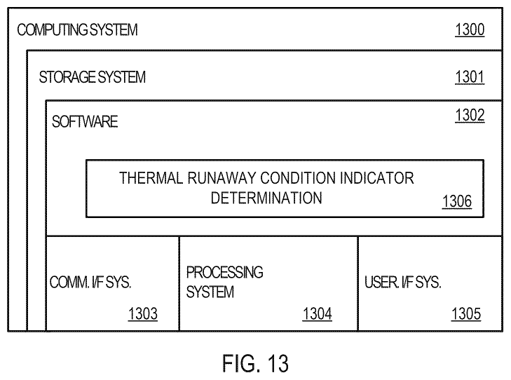

FIG. 13 illustrates a computing system 1300 to perform thermal runaway condition indicator determination according to an implementation of the present technology. Computing system 1300 is representative of any system or collection of systems with which the various operational architectures, processes, scenarios, and sequences disclosed herein for performing thermal runaway condition indicator determination processes may be employed. Computing system 1300 may be implemented as a single apparatus, system, or device or may be implemented in a distributed manner as multiple apparatuses, systems, or devices. Computing system 1300 includes, but is not limited to, storage system 1301, software 1302, communication interface system 1303, processing system 1304, and user interface system 1305 (optional). Processing system 1304 is operatively coupled with storage system 1301, communication interface system 1303, and user interface system 1305. Computing system 1300 may be representative of a cloud computing device, distributed computing device, or the like.

Processing system 1304 loads and executes software 1302 from storage system 1301. Software 1302 includes and implements thermal runaway condition indicator determination 1306, which is representative of any of the methods 700, 1200 described herein. When executed by processing system 1304 to detect indicators of imminent thermal runaway event conditions, software 1302 directs processing system 1304 to operate as described herein for at least the various processes, operational scenarios, and sequences discussed in the foregoing implementations. Computing system 1300 may optionally include additional devices, features, or functionality not discussed for purposes of brevity.

Referring still to FIG. 13, processing system 1304 may comprise a micro-processor and other circuitry that retrieves and executes software 1302 from storage system 1301. Processing system 1304 may be implemented within a single processing device but may also be distributed across multiple processing devices or sub-systems that cooperate in executing program instructions. Examples of processing system 1304 include general purpose central processing units, graphical processing units, application specific processors, and logic devices, as well as any other type of processing device, combinations, or variations thereof.

Storage system 1301 may comprise any computer readable storage media readable by processing system 1304 and capable of storing software 1302. Storage system 1301 may include volatile and nonvolatile, removable and non-removable media implemented in any method or technology for storage of information, such as computer readable instructions, data structures, program modules, or other data. Examples of storage media include random access memory, read only memory, magnetic disks, optical disks, optical media, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 1301 may also include computer readable communication media over which at least some of software 1302 may be communicated internally or externally. Storage system 1301 may be implemented as a single storage device but may also be implemented across multiple storage devices or sub-systems co-located or distributed relative to each other. Storage system 1301 may comprise additional elements, such as a controller capable of communicating with processing system 1304 or possibly other systems.

Software 1302 (including thermal runaway condition indicator determination 1306) may be implemented in program instructions and among other functions may, when executed by processing system 1304, direct processing system 1304 to operate as described with respect to the various operational scenarios, sequences, and processes illustrated herein. For example, software 1302 may include program instructions for implementing thermal runaway event indicator determination processes as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 1302 may include additional processes, programs, or components, such as operating system software, virtualization software, or other application software. Software 1302 may also comprise firmware or some other form of machine-readable processing instructions executable by processing system 1304.

In general, software 1302 may, when loaded into processing system 1304 and executed, transform a suitable apparatus, system, or device (of which computing system 1300 is representative) overall from a general-purpose computing system into a special-purpose computing system customized to provide thermal runaway condition indicator detection process performance as described herein. Indeed, encoding software 1302 on storage system 1301 may transform the physical structure of storage system 1301. The specific transformation of the physical structure may depend on various factors in different implementations of this description. Examples of such factors may include, but are not limited to, the technology used to implement the storage media of storage system 1301 and whether the computer-storage media are characterized as primary or secondary storage, as well as other factors.

For example, if the computer readable storage media are implemented as semiconductor-based memory, software 1302 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 1303 may include communication connections and devices that allow for communication with other computing systems (not shown) over communication networks (not shown). Examples of connections and devices that together allow for inter-system communication may include network interface cards, antennas, power amplifiers, radiofrequency circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication interface system 1303 may communicate with sensors and input devices such as the voltage measurement devices 812 of FIG. 8. Additionally, it is observable that the ambient temperature affects battery overpotential. Accordingly, communication interface system 1303 may also communicate with one or more temperature sensors (not shown) to compare observed changes with the ambient temperature. In one embodiment, temperature calibration curves may be included and consulted to help determine what behavior a given battery should exhibit at a given cycle and temperature.

Communication between computing system 1300 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of networks, or variation thereof. The aforementioned communication networks and protocols are well known and need not be discussed at length here.

The techniques described herein provide advanced warning of a possible thermal runaway event. The warning can be used to stop a cell during cycling and then slowly discharge it to prevent thermal runaway. Cells stopped in this manner can then undergo root-cause analysis. Either the overpotential aspect of FIGS. 4-7 or the charging voltage aspect of FIGS. 9-12 may indicate the imminent occurrence of a thermal runaway event. This is strengthened by observance of expected behavior in other aspects of battery operation. For example, as cells cycle the expected performance loss is often quantified by a depressed voltage during discharge or an increase in end-of-charge overpotential. Observing these usual performance-loss signals in tandem with the anomalous signal is a good indication of imminent thermal runaway.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the present disclosure. Additionally, while various embodiments of the present disclosure have been described, it is to be understood that aspects of the present disclosure may include only some of the described embodiments. Accordingly, the invention is not to be seen as limited by the foregoing description but is only limited by the scope of the appended claims.

What is claimed is:

1. A method for determining a condition indicating imminent thermal runaway in a power source comprising:
changing a state of charge of the power source during one of a plurality of charge cycles and a plurality of discharge cycles;
in response to the state of charge in each of the one of the plurality of charge cycles and the plurality of discharge cycles matching a first condition:
measuring the state of charge of the power source; and
determining an overpotential value based on the measured state of charge;
determining a trend based on a plurality of the overpotential values; and
identifying an indication of possible thermal runaway in the power source based on the trend indicating a downward trend of the plurality of overpotential values.

2. The method of claim 1 further comprising storing the determined overpotential value of each of the one of the plurality of charge cycles and the plurality of discharge cycle in a database.

3. The method of claim 2, wherein determining the trend comprises:
comparing a first overpotential value to an average value of a subset of overpotential values of the database; and
determining the trend based on the first overpotential value being lower than the average value.

4. The method of claim 3, wherein the first overpotential value comprises a most-recent determined overpotential value; and
wherein the subset of overpotential values comprises overpotential values determined prior to the first overpotential value.

5. The method of claim 1, wherein identifying the indication of possible thermal runaway comprises identifying the indication of possible thermal runaway after a settling period of downwardly trending overpotential values.

6. The method of claim 1 further comprising:
charging or discharging the power source to a predetermined level in each of a plurality of subsequent cycles of the respective one of a plurality of charge cycles and a plurality of discharge cycles;
allowing the power source to rest in response to reaching the predetermined level of charge or discharge and prior to measuring the state of charge of the power source.

7. The method of claim 1 further comprising isolating the power source from further charging and discharging cycles in response to identifying the indication of possible thermal runaway.

8. The method of claim 7 further comprising connecting the power source to an auxiliary power source; and
applying a slow discharging signal to the power source during discharging cycles to mitigate a risk of thermal runaway.

9. The method of claim 7 further comprising connecting the power source to an auxiliary power source; and
applying an AC signal to the power source during discharging cycles to mitigate a risk of thermal runaway.

10. The method of claim 1, wherein the power source comprises a solid-state battery.

11. An apparatus comprising:
one or more computer readable storage media;
program instructions stored on the one or more computer readable storage media, the program instructions executable by a processing system to direct the processing system to:
change a state of charge of the power source during one of a plurality of charge cycles and a plurality of discharge cycles;
measure the state of charge of the power source in each of the one of the plurality of charge cycles and the plurality of discharge cycles;
determine an overpotential value based on the measured state of charge;
compare the determined overpotential value with one or more previously determined overpotential values; and
identify an indication of possible thermal runaway in the power source based on the comparison.

12. The apparatus of claim 11, wherein the program instructions further direct the processing system to:
acquire the one or more previously determined overpotential values from a historical database of stored overpotential values.

13. The apparatus of claim 11, wherein the program instructions further direct the processing system to:
determine a trend of the determined overpotential value compared to the one or more previously determined overpotential values; and
identify the indication of possible thermal runaway based on the trend being a downward trend.

14. The apparatus of claim 13, wherein the program instructions further direct the processing system to:
determine the trend based on the determined overpotential value being lower than an average of the one or more previously determined overpotential values.

15. The apparatus of claim 11, wherein the program instructions further direct the processing system to:
measure the state of charge of the power source in each of the one of the plurality of charge cycles and the plurality of discharge cycles after a resting period following the state of charge of the power source reaching a threshold during the one of a plurality of charge cycles and a plurality of discharge cycles.

16. The apparatus of claim 11, wherein the program instructions further direct the processing system to:
isolate the power source from further charging and discharging cycles in response to identifying the indication of possible thermal runaway.

17. A system comprising:
a DC power source;
a power supply; and
a controller configured to:
cause the power supply to charge the DC power source during each of a plurality of charge cycles;
determine an overpotential value for each of the plurality of charge cycles;
compare the overpotential value with one or more historical overpotential values; and
identify an indication of possible thermal runaway in the DC power source in response to an indication of a downward trend of the overpotential value in relation to the one or more historical overpotential values.

18. The system of claim 17, wherein the controller is further configured to:
isolate the DC power source from further charging cycles in response to identifying the indication of possible thermal runaway.

19. The system of claim 17, wherein the controller, in being configured to determine the overpotential value, is further configured to:
cease the charging of the DC power source in response to a state of charge of the DC power source reaching a target value; and
allow the state of charge to rest;
measure the state of charge after the rest; and
determine the overpotential value based on a comparison of the measured state of charge to the target value.

20. The system of claim 17, wherein the controller, in being configured to identify the indication of possible thermal runaway, is further configured to:
identify the indication of possible thermal runaway in the DC power source after an upward trend of the overpotential value.
